(19) United States
(12) Patent Application Publication
(10) Pub. No.: US 2012/0064248 A1
(43) Pub. Date: Mar. 15, 2012

(54) METHOD FOR FORMING CU FILM AND STORAGE MEDIUM

(75) Inventors: Yasuhiko Kojima, Nirasaki-shi (JP); Kenji Hiwa, Nirasaki-shi (JP)

(73) Assignee: TOKYO ELECTRON LIMITED, Tokyo (JP)

(21) Appl. No.: 13/229,018

(22) Filed: Sep. 9, 2011

Related U.S. Application Data
(63) Continuation of application No. PCT/JP2010/051610, filed on Feb. 4, 2010.

(30) Foreign Application Priority Data
Mar. 11, 2009 (JP) 2009-058191

(51) Int. Cl. C23C 16/06; C23C 16/44

(52) U.S. Cl. 427/252; 118/696

(57) ABSTRACT

In a method for forming a Cu film, a substrate is loaded in a processing chamber and a gaseous film-forming source material including monovalent amidinate copper and a gaseous reducing agent including a carboxylic acid are introduced into the processing chamber. Then, a Cu film is deposited on the substrate by reacting the film-forming source material and the reducing agent together on the substrate.

This application is a Continuation Application of PCT International Application No. PCT/JP2010/051610 filed on Feb. 4, 2010, which designated the United States.

### FIELD OF THE INVENTION

The present invention relates to a method for forming a Cu film by chemical vapor deposition (CVD) on a substrate such as a semiconductor substrate or the like, and a storage medium.

### BACKGROUND OF THE INVENTION

Recently, along with the trend toward high speed of semiconductor devices and miniaturization of wiring patterns, Cu having higher conductivity and electromigration resistance than Al attracts attention as a material for wiring, a Cu plating seed layer, and a contact plug.

As for a method for forming a Cu film, physical deposition vapor (PVD) has been widely used. However, it is disadvantageous in that a step coverage becomes poor due to miniaturization of semiconductor devices.

Therefore, as for a method for forming a Cu film, there is used CVD for forming a Cu film on a substrate by a thermal decomposition reaction of a source gas containing Cu or by a reduction reaction of the source gas by a reducing gas. A Cu film formed by CVD (CVD-Cu film) has a high step coverage and a good film formation property for a thin, long and deep pattern. Thus, the Cu film has high conformability to a fine pattern and is suitable for formation of wiring, a Cu plating seed layer and a contact plug.

A scientific treatise has been published in which monovalent amidinate copper is used as a film-forming source material (precursor) and H₂ or NH₃ is used as a reducing agent for a Cu film formation using CVD (see, e.g., J. Electrochem. Soc. 153(11) C787 (2006)).

However, in the CVD using the amidinate copper and H₂ or NH₃, a reaction is practically hard to occur under a very low concentration water atmosphere, a high temperature of 300° C. or more is required for the film formation, and a film formation rate is low. This may result in reduction of Cu film surface migration and growth of island-like agglomerations of Cu during film formation, thereby making it difficult to achieve a smooth Cu film. In addition, the low film forming rate may result in an impractical semiconductor process.

### SUMMARY OF THE INVENTION

The present invention provides a Cu film forming method which is capable of forming a CVD-Cu film having good surface property at a practical film formation rate under a low temperature condition by using monovalent amidinate copper as a film-forming source material.

Further, the present invention provides a storage medium which stores a program executed to achieve such a Cu film forming method.

The present inventors have found that, by using monovalent amidinate copper as a film-forming source material and a carboxylic acid as a reducing agent, a Cu film having a good surface property can be formed under a low temperature condition and at a film forming rate adaptable to a semiconductor process, and have achieved the present invention.

In accordance with an aspect of the present invention, there is provided a method for forming a Cu film, including: loading a substrate in a processing chamber; introducing a gaseous film-forming source material including monovalent amidinate copper and a gaseous reducing agent including a carboxylic acid into the processing chamber; and depositing a Cu film on the substrate by reacting the film-forming source material and the reducing agent together on the substrate.

In accordance with another aspect of the present invention, there is provided a computer readable storage medium storing a program for controlling a film forming apparatus, wherein the program, when executed by a computer, controls the film forming apparatus to perform a method for forming a Cu film, the method including: loading a substrate in a processing chamber; introducing a gaseous film-forming source material including monovalent amidinate copper and a gaseous reducing agent including a carboxylic acid into the processing chamber; and depositing a Cu film on the substrate by reacting the film-forming source material and the reducing agent together on the substrate.

### BRIEF DESCRIPTION OF THE DRAWINGS

FIG. 1 is a substantial cross sectional view showing an exemplary configuration of a film forming apparatus for performing a film forming method in accordance with an embodiment of the present invention.

FIG. 2 is a timing diagram showing an exemplary sequence of film formation.

FIG. 3 is a timing diagram showing another exemplary sequence of film formation.

FIG. 4 is a graph showing relationships between film formation time and film thickness in cases when a CVD-Cu film is formed at 135° C. and 150° C. using [Cu(sBu-Me-amd)]₂ and a formic acid, respectively.

FIG. 5 is a scanning electron microscopic (SEM) photograph showing a section of a CVD-Cu film formed using [Cu(sBu-Me-amd)]₂ and a formic acid.

### DETAILED DESCRIPTION OF THE EMBODIMENT

Hereinafter, an embodiment of the present invention will be described in detail with reference to the accompanying drawings which form a part hereof.

(Configuration of a film forming apparatus for performing a film forming method in accordance with an embodiment of the present invention)

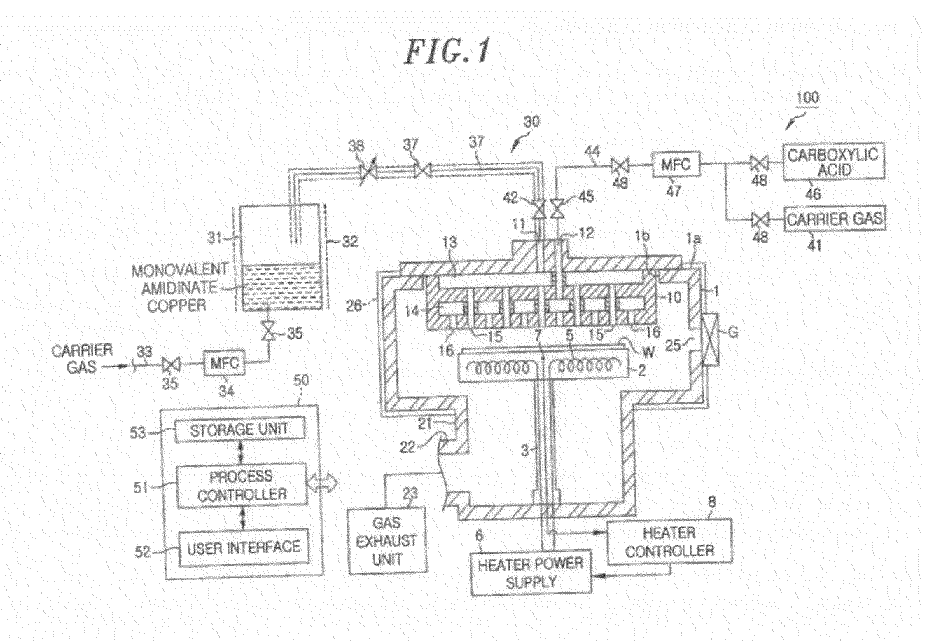

FIG. 1 is a substantial cross sectional view showing an exemplary configuration of a film forming apparatus for performing a film forming method in accordance with an embodiment of the present invention.

A film forming apparatus 100 includes a substantially cylindrical airtight chamber 1 as a processing chamber, and a susceptor 2 provided in the chamber 1. The susceptor 2 for horizontally supporting a semiconductor wafer W as a substrate to be processed is supported by a cylindrical supporting member 3 provided at the center of the bottom portion of the chamber 1. The susceptor 2 is made of ceramic such as AlN or the like.

Further, a heater 5 is buried in the susceptor 2, and a heater power supply 6 is connected to the heater 5. Meanwhile, a thermocouple 7 is provided near the top surface of the susceptor 2, and a signal from the thermocouple 7 is transmitted to a heater controller 8. The heater controller is configured to transmit an instruction to the heater power supply 6 in accordance with the signal from the thermocouple 7 and control the wafer W to a predetermined temperature by controlling the heating of the heater 5.

A circular opening 1b is formed at a ceiling wall 1a of the chamber 1, and a shower head 10 is fitted in the circular opening 1b to protrude in the chamber 1. The shower head 10 injects a film forming gas supplied from a gas supply mechanism 30 to be described later into the chamber 1. The shower head 10 has, at an upper portion thereof, a first inlet line 11 for introducing monovalent amidinate copper, for example, Cu(I)N,N′-di-secondary-butylacetoamidinate ([Cu(sBu-Me-amd)]₂), as a film-forming source material and a second inlet 12 for introducing a reducing agent into the chamber 1.

The first inlet 11 and the second inlet 12 are separately provided within the shower 10 and the film forming source gas and the reducing agent are mixed together after being injected in the chamber 1.

The inner space of the shower head 10 is separated into an upper space 13 and a lower space 14. The first inlet line 11 is connected to the upper space 13, and a first gas injection path 15 extends from the upper space 13 to the bottom surface of the shower head 10. The second inlet line 12 is connected to the lower space 14, and a second gas injection path 16 extends from the lower space 14 to the bottom surface of the shower head 10. In other words, the shower head 10 is configured to separately inject the monovalent amidinate copper as the film-forming source material and a carboxylic acid as the reducing agent through the outlets 15 and 16, respectively.

A gas exhaust chamber 21 is provided at a bottom wall of the chamber 1 so as to protrude downward. A gas exhaust line 22 is connected to a side wall of a gas exhaust chamber 21, and a gas exhaust unit 23 including a vacuum pump, a pressure control valve and the like is connected to the gas exhaust line 22. By driving the gas exhaust unit 23, the inside of the chamber 1 can be set to a predetermined depressurized state.

Formed on the sidewall of the chamber 1 are a loading/unloading port 24 for loading and unloading the wafer W with respect to a wafer transfer chamber (not shown) and a gate valve G for opening and closing the loading/unloading port 24. Moreover, a heater 26 is provided on a wall of the chamber 1, and can control the temperature of the inner wall of the chamber 1 during the film formation.

The gas supply mechanism 30 has a film-forming source material tank 31 for storing, as a film-forming source material, monovalent amidinate copper, for example, Cu(I)N,N′-di-secondary-butylacetoamidinate ([Cu(sBu-Me-amd)]₂). Other examples of monovalent amidinate copper include Cu(I)N,N′-di-tertiary-butylacetoamidinate ([Cu(tBu-Me-amd)]₂), Cu(I)N,N′-di-isoprophylacetoamidinate ([Cu(iPr-Me-amd)]₂) and the like.

Since the monovalent amidinate copper is typically in a solid state at a room temperature, a heater 32 is provided around the film-forming source material tank 31 to heat and liquefy the monovalent amidinate copper. In addition, a carrier gas line 33 for feeding a carrier gas, e.g., Ar gas, is connected to the bottom of the film-forming source material tank 31. A mass flow controller 34 and two valves 35 are provided on the carrier gas line 33 with the mass flow controller 34 interposed between the valves 35. In addition, a film-forming source material feeding line 36 has one end connected to the top of the film-forming source material tank 31 and the other end connected to the first inlet 11. The monovalent amidinate copper heated and liquefied by the heater 32 is bubbled into a gaseous state by the carrier gas fed from the carrier gas line 33, which is then fed into the shower head 10 via the film-forming source material feeding line 36 and the first inlet 11. A heater 37 to prevent the gaseous film-forming source material from being liquefied is provided around the film-forming source material feeding line 36. On the film-forming source material feeding line 36 are provided a flow rate control valve 38, an opening/closing valve 39 at the downstream side of the valve 38, and an opening/closing valve 40 adjacent to the first inlet 11.

A reducing agent feeding line 44 for feeding the carboxylic acid as the reducing agent is connected to the second inlet 12 of the shower head 10. A carboxylic acid supply source 46 for supplying the carboxylic acid gas as the reducing agent is connected to the reducing agent feeding line 44. A valve 45 is provided, near the second inlet 12, on the reducing agent feeding line 44. In addition, a mass flow controller 47 and two valves 48 are provided on the reducing agent feeding line 44 with the mass flow controller 47 interposed between the valves 48. A carrier gas feeding line 44a is branched from the reducing agent feeding line 44 at the upstream side of the mass flow controller 47 and a carrier gas supply source 41 is connected to the carrier gas feeding line 44a. The carboxylic acid as the reducing agent for reducing the monovalent amidinate copper is supplied into the chamber 1 from the carboxylic acid supply source 46 via the reducing agent feeding line 44 and the shower head 10. In addition, the carrier gas, e.g., Ar gas, is supplied into the chamber 1 from the carrier gas supply source 41 via the carrier gas feeding line 44a, the reducing agent feeding line 44 and the shower head 10. The carboxylic acid as the reducing agent may be a formic acid (HCOOH) or acetic acid (CH₃COOH).

The film forming apparatus 100 includes a control unit 50 which is configured to control the respective components, e.g., the heater power supply 6, the gas exhaust unit 23, the mass flow controllers 34 and 47, the flow rate control valve 38, the valves 35, 39, 40, 45, 48 and the like, and control the temperature of the susceptor 2 by using the heater controller 8. The control unit 50 includes a process controller 51 having a micro processor (computer), a user interface 52 and a storage unit 53. The respective components of the film forming apparatus 100 are electrically connected to and controlled by the process controller 51.

The user interface 52 is connected to the process controller 51, and includes a keyboard through which an operator performs a command input to manage the respective units of the film forming apparatus 100, a display for visually displaying the operational states of the respective components of the film forming apparatus 100, and the like.

The storage unit 53 is also connected to the process controller 51, and stores therein control programs to be used in realizing various processes performed by the film forming apparatus 100 under the control of the process controller 51, control programs, i.e., processing recipes, to be used in operating the respective components of the film forming apparatus 100 to carry out predetermined processes under processing conditions, various database and the like. The processing recipes are stored in a storage medium (not shown) provided in the storage unit 53. The storage medium may be a fixed medium such as a hard disk or the like, or a portable device such as a CD-ROM, a DVD, a flash memory or the like. Alternatively, the recipes may be suitably transmitted from other devices via, e.g., a dedicated transmission line.

If necessary, a predetermined processing recipe is read out from the storage unit 53 by the instruction via the user interface 52 and is executed by the process controller 51. Accordingly, a desired process is performed in the film forming apparatus 100 under the control of the process controller 51.

(Cu Film Forming Method in Accordance with the Embodiment of the Present Invention)

Hereinafter, a method for forming a Cu film in accordance with the present embodiment which uses the film forming apparatus configured as described above will be described.

For formation of a Cu film, first, the gate valve G is opened and a wafer W is loaded in the chamber 1 by a transfer mechanism (not shown) to be mounted on the susceptor 2. As the wafer W, a wafer whose surface is formed with an underlayer of a Cu film is used. The underlayer is preferably a Ru film (CVD-Ru film) formed by CVD. The CVD-Ru film is preferably formed by using Ru₃(CO)₁₂ as film-forming source material. Accordingly, a CVD-Ru film of high purity can be obtained, and a pure and robust interface between Cu and Ru can be formed.

Next, the chamber 1 is exhausted by the gas exhaust unit 23 to set the internal pressure of the chamber 1 to be 1.33 to 1333 Pa (10 mm Torr to 10 Torr), the susceptor 2 is heated by the heater 5 to set the temperature of the susceptor 2 (i.e., wafer temperature) to be equal to or less than about 200° C., preferably 120 to 190° C., and a carrier gas for is supplied into the chamber 1 at a flow rate of 100 to 1500 mL/min (sccm) from the carrier gas supply source 41 via the carrier gas feeding line 44a, the reducing agent feeding line 44 and the shower head 10. In this way, the stabilization is carried out.

When the interior of the chamber 1 becomes stabilized under the predetermined conditions, the carrier gas is supplied into the film-forming source material tank 31, which is heated to, for example, 90 to 120° C. by the heater 32, at a flow rate of 100 to 1500 mL/min (sccm) through the pipe 33, monovalent amidinate copper, for example, Cu(I)N,N′-di-secondary-butylacetoamidinate ([Cu(sBu-Me-amd)]₂), bubbled into a gaseous state, is introduced into the chamber 1 through the film-forming source material feeding line 36 and the shower head 10, and a gaseous carboxylic acid as a reducing agent is introduced into the chamber 1 from the carboxylic acid supply source 46 via the reducing agent feeding pipe 44 and the shower head 10.

Then, the monovalent amidinate copper as the film-forming source material reacts with the carboxylic acid as the reducing agent on the wafer, so that Cu is deposited on the wafer. Consequently, a Cu film having a predetermined film thickness is formed on the wafer by performing such Cu deposition for a predetermined period of time.

The monovalent amidinate copper has a structural formula expressed by the following chemical formula 1. Typically, the monovalent amidinate copper is in a solid state at the room temperature and has a melting point of 70 to 90° C. As expressed by the chemical formula 1, two Cu atoms in the monovalent amidinate copper are each bonded to two N atoms. Cu is obtained by cutting this bonding by means of the carboxylic acid as the reducing agent.

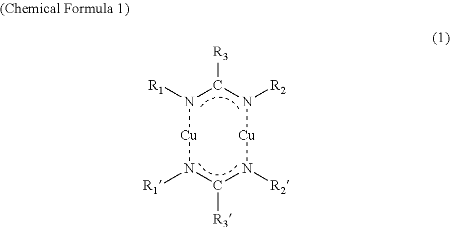

Where, R₁, R₂, R₃, R₁′, R₂′ and R₃′ represent hydrocarbon functional groups.

Cu(I)N,N′-di-secondary-butylacetoamidinate ([Cu(sBu-Me-amd)]₂) as one example of the monovalent amidinate copper has a melting point of 77° C. and its liquid vapor pressure is equal to or less than 133 Pa (1.0 Torr) at 95° C. A structural formula of [Cu(sBu-Me-amd)]₂ is expressed by the following chemical formula 2.

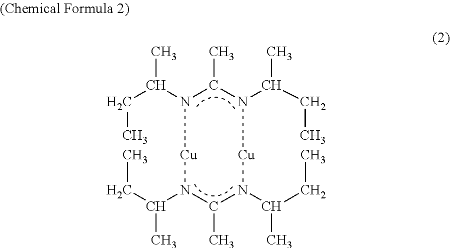

The carboxylic acid used as the reducing agent is preferably formic acid (HCOOH) and acetic acid (CH₃COOH) having very high reducibility, as described above. Among these, the formic acid is more preferable.

In a film forming process under the conditions that the temperature of the source material tank is 95° C. and the internal pressure of the tank is 10 Torr, a flow rate of [Cu(sBu-Me-amd)]₂ as the monovalent amidinate copper is 10 to 170 mL/min (sccm) in a range of flow rate of 100 to 1500 mL/min (sccm) of the carrier gas. In addition, a flow rate of the carboxylic acid as the reducing agent is 1 to 1000 mL/min (sccm).

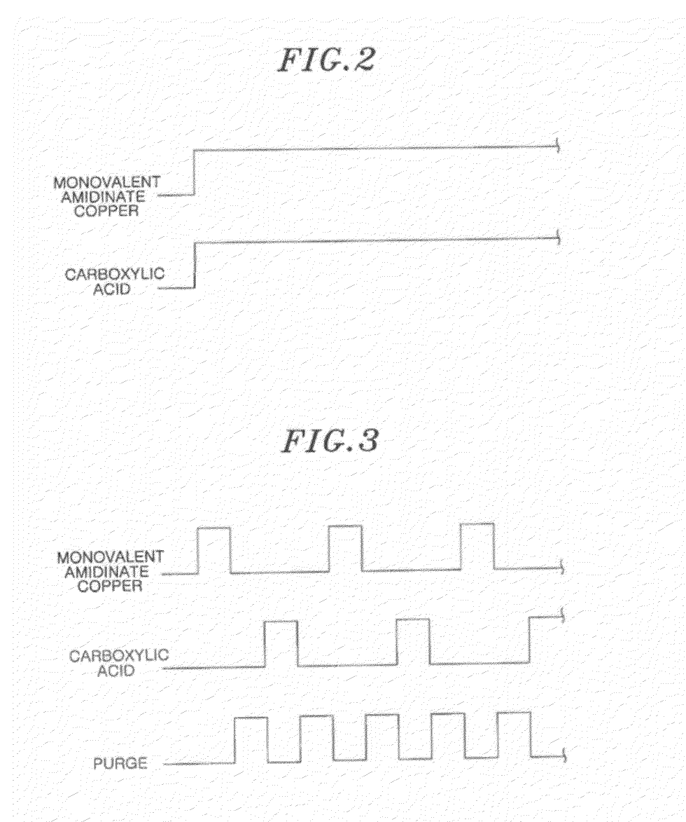

A film forming sequence may be a typical CVD process in which the monovalent amidinate copper as the film-forming source material and the carboxylic acid as the reducing agent are supplied simultaneously, as shown in FIG. 2. Alternatively, as shown in FIG. 3, a so-called ALD method of alternately supplying the monovalent amidinate copper and the carboxylic acid as the reducing agent while performing a purging operation therebetween may be used. The purging operation may be performed by supplying a carrier gas. The ALD method may further decrease a film forming temperature.

After forming the Cu film in this manner, a purge process is performed. In the purge process, after the supply of the monovalent amidinate copper is stopped by stopping the supply of the carrier gas into the film-forming source material tank 31, the vacuum pump of the exhauster 23 is set in a pull-end state and the carrier gas as a purge gas to purge the chamber 1 is introduced from the carrier gas supply source 41 into the chamber 1. In this case, it is preferable that the carrier gas is intermittently introduced in order to purge the chamber 1 as quickly as possible.

After the purge process is completed, the gate valve G is opened and the wafer W is carried out by the transfer mechanism (not shown) through the loading/unloading port 24. Thus, a series of processes for one wafer W is completed.

In this manner, when the CVD is performed for the monovalent amidinate copper as the film-forming source material while using the carboxylic acid as the reducing agent, since the carboxylic acid has high reducibility for the monovalent amidinate copper, it is possible to form the Cu film at a low temperature, e.g., at about 200° C. or less and at a practical film forming rate. If formic acid (HCOOH) or acetic acid (CH₃COOH) having very high reducibility is used as the reducing agent, it is possible to form the Cu film at a low temperature within a range of 110 to 150° C. In addition, since the Cu film can be formed at such low temperature and practical film forming rate, Cu is hardly agglomerated and a Cu film having a good surface property can be obtained.

The CVD-Cu film formed thus can be used as wiring material or a seed layer of Cu plating.

### Example

Hereinafter, one example of actually forming a CVD-Cu film by using the apparatus of FIG. 1 will be described. In this example, a Cu film was formed on a wafer by using Cu(I)N,N′-di-secondary-butylacetoamidinate ([Cu(sBu-Me-amd)]₂) as a film-forming source material and formic acid (HCOOH) as a reducing agent.

Film forming conditions were as follows. The heating temperature of the film-forming source material tank 31 was 100° C. and a flow rate of a carrier gas into the film-forming source material tank 31 was 100 mL/min (sccm). The liquid formic acid was decompressed to be evaporated so that the gaseous formic acid was supplied. The film was formed under the condition that the susceptor temperature (wafer temperature was set to 135° C. and 150° C. while changing film formation time.

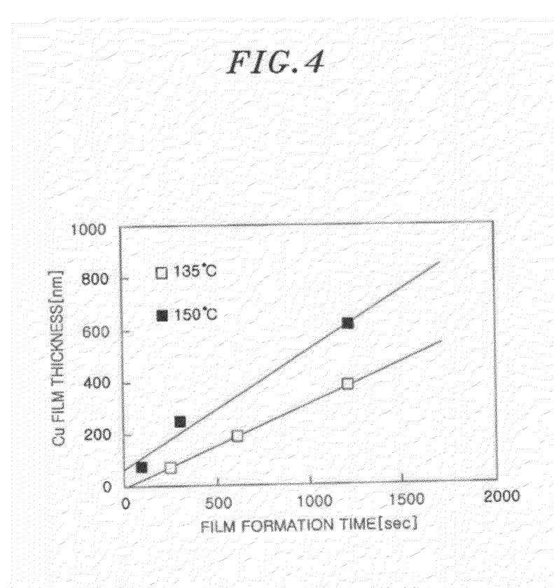

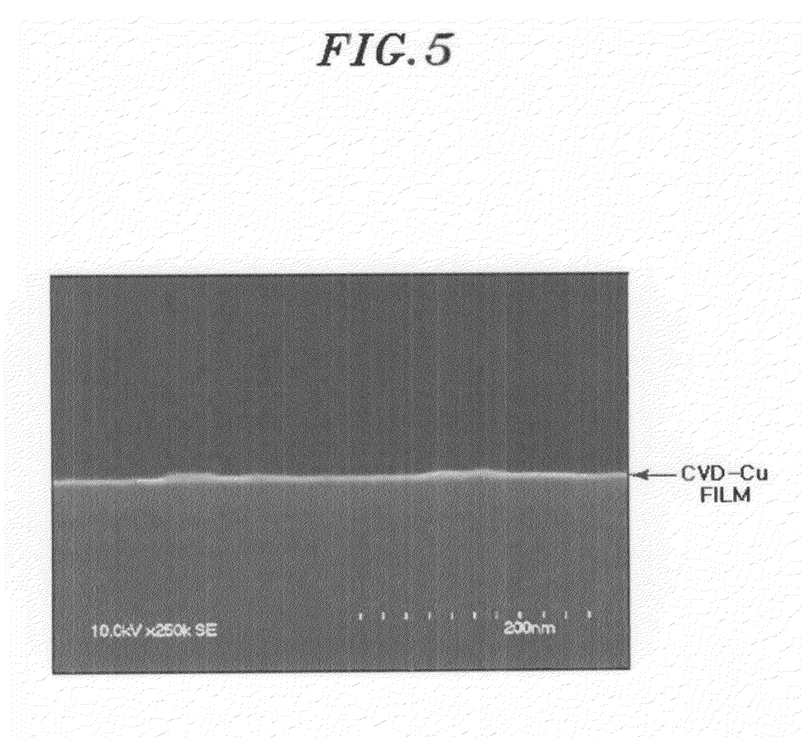

FIG. 4 shows relationships between the film formation time and the film thickness during the film formation. As shown in FIG. 4, it was confirmed that a Cu film having a practical film thickness was formed even at a low temperature of 135° C. and 150° C. FIG. 5 is a scanning electron microscopic (SEM) photograph showing a section of the formed Cu film, from which it is confirmed that a Cu film having a good surface property is obtained.

(Modifications of the Present Invention>

The present invention can be modified in various ways without being limited to the above embodiment. For example, although, as the monovalent amidinate copper of the film-forming source material, Cu(I)N,N′-di-secondary-butylacetoamidinate ([Cu(sBu-Me-amd)]₂) has been exemplified in the above embodiment, the monovalent amidinate copper may be Cu(I)N,N′-di-tertiary-butylacetoamidinate ([Cu(tBu-Me-amd)]₂), Cu(I)N,N′-di-isoprophylacetoamidinate ([Cu(iPr-Me-amd)]₂) or the like. In addition, the carboxylic acid as the reducing agent is not limited to the formic acid and acetic acid but may be a propionic acid, a butyric acid, a valeric acid or other carboxylic acids. In addition, although the CVD-Ru film has been exemplified as the underlayer for film formation, the present invention is not limited thereto.

In addition, the supply method of the monovalent amidinate copper as film-forming source material is not limited to the above embodiment but may employ other different methods. In addition, the film forming apparatus is not limited to the above embodiment but may employ other various apparatuses including, e.g., a mechanism for forming plasma to promote decomposition of film-forming source material.

In addition, although the semiconductor wafer has been exemplified as a substrate to be processed, other substrates such as a flat panel display (FPD) substrate may be used as the substrate to be processed.

While the invention has been shown and described with respect to the embodiments, it will be understood by those skilled in the art that various changes and modifications may be made without departing from the scope of the invention as defined in the following claims.

What is claimed is:

1. A method for forming a Cu film, comprising:
loading a substrate in a processing chamber;
introducing a gaseous film-forming source material including monovalent amidinate copper and a gaseous reducing agent including a carboxylic acid into the processing chamber; and
depositing a Cu film on the substrate by reacting the film-forming source material and the reducing agent together on the substrate.

2. The method of claim 1, wherein the monovalent amidinate copper included in the film-forming source material is Cu(I)N,N′-di-secondary-butylacetoamidinate.

3. The method of claim 1, wherein the carboxylic acid as the reducing agent is a formic acid.

4. The method of claim 1, wherein the carboxylic acid as the reducing agent is an acetic acid.

5. The method of claim 1, wherein a temperature of the substrate during the film formation is set to be equal to or less than about 200° C.

6. The method of claim 1, wherein the film-forming source material including the monovalent amidinate copper and the reducing agent including the carboxylic acid are simultaneously introduced into the processing chamber.

7. The method of claim 1, wherein the film-forming source material including the monovalent amidinate copper and the reducing agent including the carboxylic acid are alternately introduced into the processing chamber with a supply of a purge gas interposed therebetween.

8. A computer readable storage medium storing a program for controlling a film forming apparatus,
Wherein the program, when executed by a computer, controls the film forming apparatus to perform a method for forming a Cu film, the method including:
loading a substrate in a processing chamber;
introducing a gaseous film-forming source material including monovalent amidinate copper and a gaseous reducing agent including a carboxylic acid into the processing chamber; and
depositing a Cu film on the substrate by reacting the film-forming source material and the reducing agent together on the substrate.
